(19) United States
(12) Patent Application Publication
(10) Pub. No.: US 2011/0267145 A1
(43) Pub. Date: Nov. 3, 2011

(54) COMPARISON APPARATUS AND SPEED-UP METHOD FOR COMPARATOR

(75) Inventors: Ming-Hau Tseng, Taoyuan County (TW); Yung-Pin Lee, Taipei County (TW); Bo-Wei Chen, Miaoli County (TW)

(73) Assignee: INDUSTRIAL TECHNOLOGY RESEARCH INSTITUTE, Hsinchu (TW)

(21) Appl. No.: 12/832,970

(22) Filed: Jul. 8, 2010

(30) Foreign Application Priority Data
Apr. 30, 2010 (TW) 99113976

(51) Int. Cl. H03F 3/45

(52) U.S. Cl. 330/261

(57) ABSTRACT

A comparison apparatus and a speed-up method for comparator are provided. The comparison apparatus consists of a comparator and a bias modulator. The bias modulator receives input signals of the comparator to provide a set of output signals modulated according to the input signals. The set of output signals dynamically adjust body voltages of transistors in a positive feedback network of the comparator to increase a switching speed of the transistors. Therefore, an operation speed of the comparator can also be increased.

### CROSS-REFERENCE TO RELATED APPLICATION

This application claims the priority benefit of Taiwan application serial no. 99113976, filed on Apr. 30, 2010. The entirety of the above-mentioned patent application is hereby incorporated by reference herein and made a part of this specification.

### BACKGROUND

1. Field of the Disclosure

The present disclosure relates to a speed-up method for a comparator. More particularly, the present disclosure relates to a speed-up method for adjusting body voltages of transistors in a positive feedback network of a comparator.

2. Description of Related Art

In various electronic products, an operation speed of a digital or analog circuit directly influences a signal processing performance of the whole system. In the digital or analog circuits with various functions, for example, a sensing amplification circuit in a memory, a flip-flop in a prescaler, and a commonly used comparison circuit in an analog-to-digital converter (ADC), etc. are all commonly used basic functional blocks. Additionally, logic circuits are further embedded in a latch circuit having a positive feedback mechanism to reduce a signal response time. Therefore, speed-up of a latching operation of the latch circuit can directly benefit the operation speed of the whole circuit system. If a latching speed of the latch circuit is increased, performances of the circuit system in various application domains can be improved.

Regarding a high-speed wireless communication system, a channel bandwidth of an input signal is an essential factor, though it is a great challenge regarding a design of an ADC. A response speed of the ADC is determined by a bandwidth of a sampling circuit and a comparing time of a comparison circuit. Therefore, it is important to reduce the comparing time of the comparison circuit to improve a sampling frequency of the ADC, so as to obtain a wider bandwidth for the input signal. Wherein, a latching time of the latch circuit determines an operation speed of the whole comparator.

To increase the operation speed of the comparator, according to the U.S. Pat. No. 6,452,448, body voltages of transistors in an input differential pair of a comparator are controlled to change threshold voltages of the transistors in the input differential pair, so as to increase a transconductance value thereof, and increase the operation speed of the comparator.

### SUMMARY

The disclosure is directed to a speed-up method for a comparator, in which a bias modulator receives input signals of the comparator to provide a set of output signals modulated according to the input signals. The set of output signals dynamically adjust body voltages of transistors in a positive feedback network of the comparator to increase switching speeds of the transistors, so as to increase the operation speed of the comparator. Wherein, the positive feedback network is implemented by a latch circuit.

The disclosure provides a comparator including an input differential pair, a latch circuit and a bias modulator. The input differential pair receives a first input signal and a second input signal. The latch circuit is coupled to the input differential pair, wherein the latch circuit includes a first transistor. The bias modulator modulates a first body voltage through a charge transfer method according to the first input signal, the second input signal and a source voltage of the first transistor, and provides the first body voltage to a body of the first transistor of the latch circuit.

The disclosure provides a speed-up method for a comparator. The comparator includes an input differential pair and a latch circuit. The input differential pair receives a first input signal and a second input signal. The latch circuit includes a first transistor. The speed-up method includes modulating a first body voltage according to the first input signal, the second input signal and a source voltage of the first transistor, and providing the first body voltage to a body of the first transistor.

According to the above descriptions, the comparator of the disclosure may provide multiple positive feedback mechanisms, which can influence a polarity of the input signal through the bias modulator, so as to dynamically adjust the body voltages of the transistors in the latch circuit and speed-up switching time of the transistors. Therefore, a comparing time of the comparator can be accelerated.

In order to make the aforementioned and other features and advantages of the present disclosure comprehensible, several exemplary embodiments accompanied with figures are described in detail below.

### BRIEF DESCRIPTION OF THE DRAWINGS

The accompanying drawings are included to provide a further understanding of the disclosure, and are incorporated in and constitute a part of this specification. The drawings illustrate embodiments of the disclosure and, together with the description, serve to explain the principles of the disclosure.

FIG. 1 is a functional block diagram illustrating a comparison apparatus according to an exemplary embodiment of the disclosure.

FIG. 2A is a circuit schematic diagram illustrating a comparator of FIG. 1 according to an exemplary embodiment of the disclosure.

FIG. 2B is a circuit schematic diagram illustrating a comparator of FIG. 1 according to another exemplary embodiment of the disclosure.

FIG. 3 is a circuit schematic diagram illustrating a bias modulator of FIG. 1 according to an exemplary embodiment of the disclosure.

FIG. 4 is a circuit schematic diagram illustrating a bias modulator of FIG. 1 according to another exemplary embodiment of the disclosure.

FIG. 5 is a circuit schematic diagram illustrating a bias modulator of FIG. 1 according to still another exemplary embodiment of the disclosure.

FIG. 6 is a circuit schematic diagram illustrating a bias modulator of FIG. 1 according to yet another exemplary embodiment of the disclosure.

### DETAILED DESCRIPTION OF DISCLOSED EMBODIMENTS

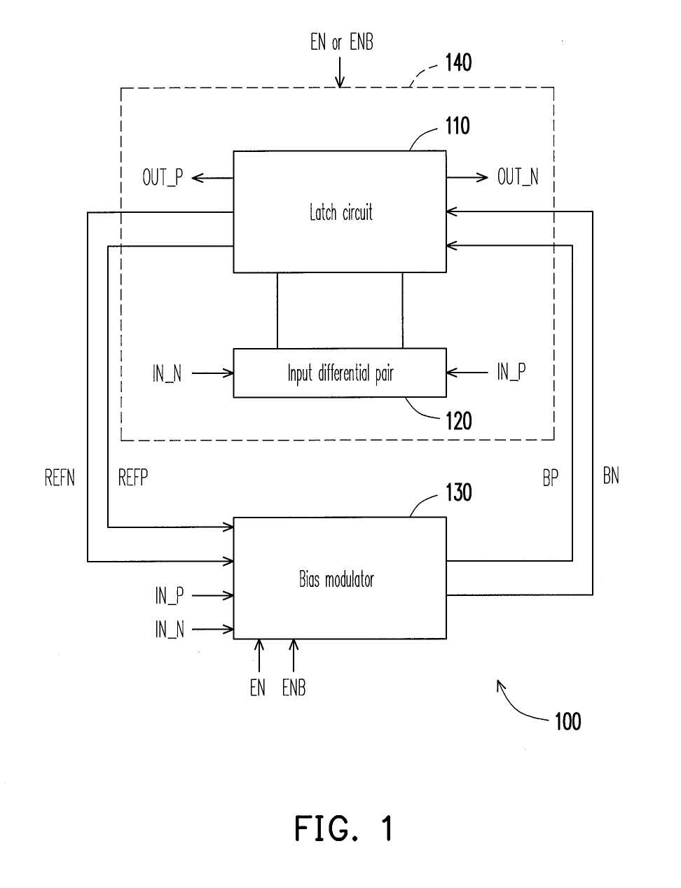

FIG. 1 is a functional block diagram illustrating a comparison apparatus 100 according to an exemplary embodiment of the disclosure. The comparison apparatus 100 includes a comparator 140 and a bias modulator 130. The comparator 140 includes a latch circuit 110 and an input differential pair 120. The input differential pair 120 receives a first input signal IN_N and a second input signal IN_P. The first input signal IN_N and the second input signal IN_P are a differential signal pair. The latch circuit 110 is coupled to the input differential pair 120. Wherein, the latch circuit 110 includes a plurality of internal transistors, and provides source voltages REFN and REFP of the internal transistors to the bias modulator 130.

The bias modulator 130 can be a body bias modulator (BBM). The bias modulator 130 receives the first input signal IN_N, the second input signal IN_P, the source voltage REFN and the source voltage REFP. The bias modulator 130 modulates and provides a first body voltage BN and a second body voltage BP to bodies of the internal transistors of the latch circuit 110 according to the first input signal IN_N, the second input signal IN_P, the source voltage REFN and the source voltage REFP. A modulation principle of the first body voltage BN and the second body voltage BP can be determined according to an actual design requirement. For example, the first body voltage BN=REFN+k(IN_N−IN_P), and the second body voltage BP=REFP+k(IN_P−IN_N), wherein k is a real number. In the present exemplary embodiment, the bias modulator 130 is used to increase a positive feedback path of the latch circuit 110, and amplify a voltage difference of the input differential signal pair (i.e. IN_P−IN_N), so as to reduce a time that the latch circuit 110 accomplishes a latching operation, and increase a comparing speed of the comparator 140 for the input differential signals.

It should be noticed that the comparator 140 of FIG. 1 applies a dynamic control structure, so that an enable signal EN (or ENB) is required to enable/disable the comparator 140.

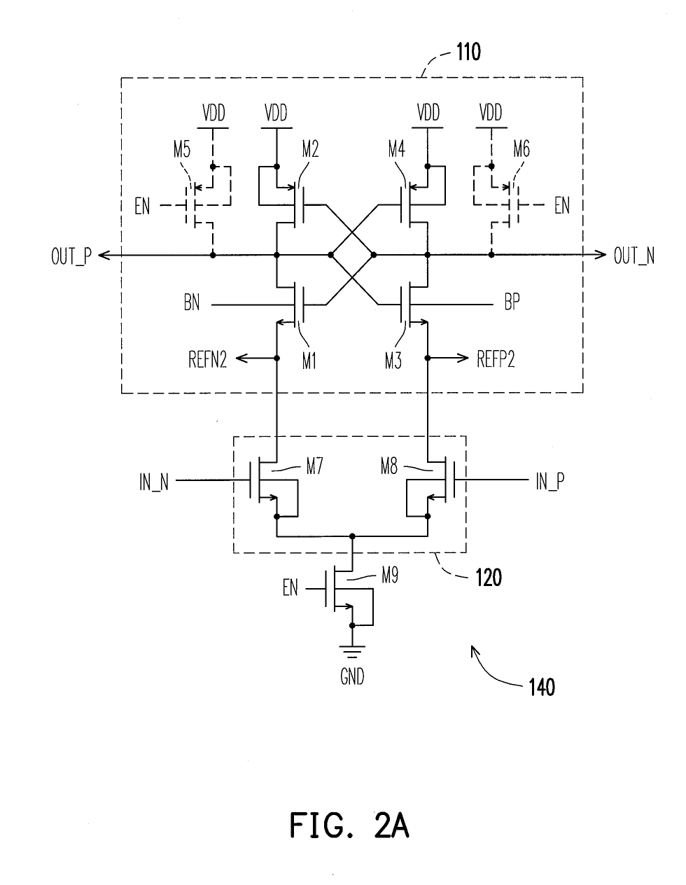

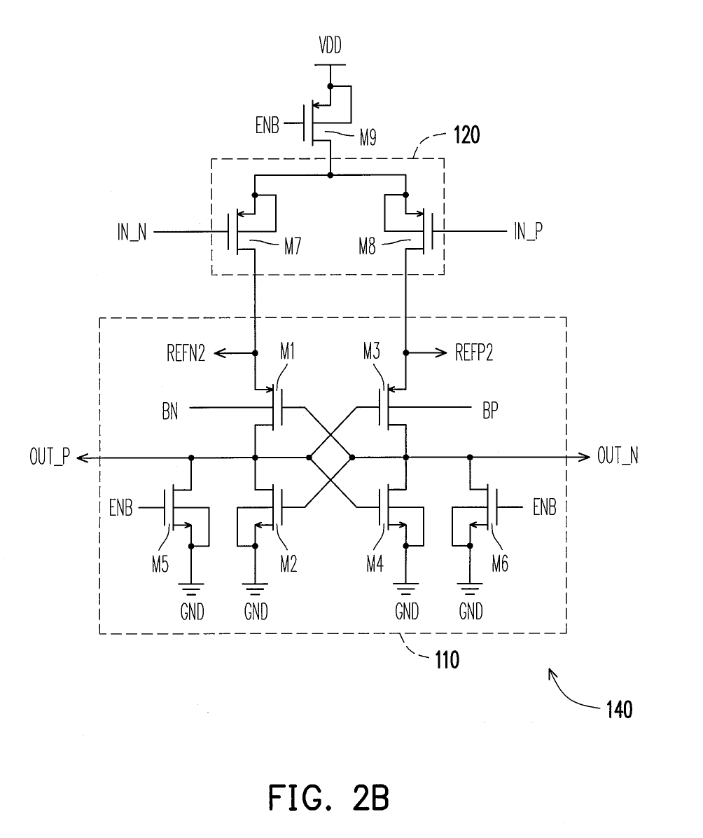

FIG. 2A is a circuit schematic diagram illustrating the comparator 140 of FIG. 1 according to an exemplary embodiment of the disclosure. The latch circuit 110 includes a first transistor M1, a second transistor M2, a third transistor M3 and a fourth transistor M4. In the present exemplary embodiment, the second transistor M2 and the fourth transistor M4 are P-channel metal oxide semiconductor (PMOS) transistors, and the first transistor M1 and the third transistor M3 are N-channel metal oxide semiconductor (NMOS) transistors. Here, the source voltages REFN and REFP of FIG. 1 are respectively implemented by a source voltage REFN2 of the first transistor M1 and a source voltage REFP2 of the third transistor M3.

Referring to FIG. 2A, a first end (for example, a drain) of the second transistor M2 is coupled to a first end (for example, a drain) of the first transistor M1, and a second end (for example, a source) of the first transistor M1 is coupled to the input differential pair 120. A control end (for example, a gate) of the second transistor M2 is coupled to a control end (for example, a gate) of the first transistor M1. A body of the first transistor M1 receives the first body voltage BN provided by the bias modulator 130. A control end (for example, a gate) of the third transistor M3 is coupled to the drain of the first transistor M1, and a first end (for example, a drain) of the third transistor M3 is coupled to the gate of the first transistor M1. A second end (for example, a source) of the third transistor M3 is coupled to the input differential pair 120. A first end (for example, a drain) of the fourth transistor M4 is coupled to the drain of the third transistor M3. A control end (for example, a gate) of the fourth transistor M4 is coupled to the gate of the third transistor M3. A body of the third transistor M3 receives the second bas voltage BP. The drains of the first transistor M1 and the third transistor M3 can serve as two output terminals of the comparator 140 to respectively generate an output signal pair OUT_P and OUT_N. In the present exemplary embodiment, second ends (for example, sources) of the second transistor M2 and the fourth transistor M4 are coupled to a system voltage VDD.

The input differential pair 120 includes a seventh transistor M7 and an eighth transistor M8. In the present exemplary embodiment, the seventh transistor M7 and the eighth transistor M8 are NMOS transistors. A first end (for example, a drain) of the seventh transistor M7 is coupled to the first transistor M1, and a control end (for example, a gate) of the seventh transistor M7 receives the first input signal IN_N. A first end (for example, a drain) of the eighth transistor M8 is coupled to the third transistor M3, and a control end (for example, a gate) of the eighth transistor M8 receives the second input signal IN_P.

A first end (for example, a drain) of a fifth transistor M5 is coupled to the drain of the first transistor M1, a second end (for example, a source) of the fifth transistor M5 is coupled to the system voltage VDD, and a control end (for example, a gate) of the fifth transistor M5 receives the enable signal EN. A first end (for example, a drain) of a sixth transistor M6 is coupled to the drain of the third transistor M3, a second end of the sixth transistor M6 is coupled to the system voltage VDD, and a control end of the sixth transistor M6 receives the enable signal EN. In the present exemplary embodiment, the fifth transistor M5 and the sixth transistor M6 are PMOS transistors.

In the present exemplary embodiment, the comparator 140 further includes a ninth transistor M9, which is implemented by an NMOS transistor. A first end (for example, a drain) of the ninth transistor M9 is coupled to second ends (for example, sources) of the seventh transistor M7 and the eighth transistor M8, a second end (for example, a source) of the ninth transistor M9 is coupled to the ground, and a control end (for example, a gate) of the ninth transistor M9 receives the enable signal EN. Therefore, the enable signal EN can enable/disable the comparator 140. Accordingly, when the comparator 140 is in a disable state, i.e. the enable signal EN has a low level (or logic 0), the enable signal EN can turn on the fifth transistor M5 and the sixth transistor M6 and turn off the ninth transistor M9, and set the output signals OUT_P and OUT_N of the comparator 140 to a high level. Conversely, when the comparator 140 is in an enable state, i.e. the enable signal EN has a high level (or logic 1), the enable signal EN can turn off the fifth transistor M5 and the sixth transistor M6 and turn on the ninth transistor M9, so that the comparator 140 compares the input differential signals. Meanwhile, the bias modulator 130 respectively transmits the modulation results of the first body voltage BN and the second body voltage BP to the bodies of the first transistor M1 and the third transistor M3 to implement a function of increasing the comparison speed of the comparator 140. In the present exemplary embodiment, although a body of the seventh transistor M7 is coupled to the source of the seventh transistor M7, and a body of the eighth transistor M8 is coupled to the source of the eighth transistor M8, the disclosure is not limited thereto. For example, in another exemplary embodiment, the bodies of the seventh transistor M7 and the eighth transistor M8 can be coupled to a ground voltage GND.

In some exemplary embodiments, the ninth transistor M9 can also be coupled between the latch circuit 110 and the system voltage VDD according to a design requirement, as that shown in FIG. 2B. FIG. 2B is a circuit schematic diagram illustrating the comparator 140 of FIG. 1 according to another exemplary embodiment of the disclosure. Here, the transistors M2, M4, M5 and M6 are implemented by NMOS transistors, and the transistors M1, M3, M7, M8 and M9 are implemented by PMOS transistors. An enable signal ENB shown in FIG. 2B is an inverted signal of the enable signal EN. The source of the ninth transistor M9 is coupled to the system voltage VDD, and the drain of the ninth transistor M9 is coupled to the sources of the first transistor M1 and the second transistor M2 through the input differential pair 120. In the present exemplary embodiment, although the body of the seventh transistor M7 is coupled to the source of the seventh transistor M7, and the body of the eighth transistor M8 is coupled to the source of the eighth transistor M8, the disclosure is not limited thereto. For example, in another exemplary embodiment, the bodies of the seventh transistor M7 and the eighth transistor M8 can be coupled to the system voltage VDD.

In a speed-up method of the disclosure, a voltage difference of source-body voltages is adjusted according to a body effect of an MOS transistor, so as to change a threshold voltage. A pattern of behaviour of the transistor's body effect is similar to a following equation (1):

V_{TH}=V_{TH0}+γ(\sqrt{2Φ_{F}+V_{SB}}−\sqrt{2Φ_{F}}) (1)

Wherein, V_{SB} represents a voltage difference between a body and a source of a transistor, V_{TH} represents a threshold voltage of the transistor, V_{TH0} represents a threshold voltage when there is none voltage difference between the body and the source of the transistor, γ represents a body effect parameter, and 2Φ is a surface potential parameter. According to the equation (1), it is known that change of the voltage difference V_{SB} can lead to a change of the threshold voltage V_{TH}. If the voltage difference V_{SB} is a positive number, the threshold voltage V_{TH} is correspondingly increased. Conversely, if the voltage difference V_{SB} is a negative number, the threshold voltage V_{TH} is correspondingly decreased. Therefore, when the source-body voltage of the first transistor M1 (or the third transistor M3) is changed, the threshold voltage thereof is accordingly changed.

Referring to FIG. 2A, when the second input signal IN_P is greater than the first input signal IN_N, the bias modulator 130 pulls high the second body voltage BP (due to BP=REFP2+k(IN_P—IN_N)), so that the second body voltage BP is greater than the source voltage REFP2 of the third transistor M3. The threshold voltage of the third transistor M3 is decreased as the second body voltage BP is pulled high, so that a turning on operation of the third transistor M3 is accelerated. Conversely, the bias modulator 130 pulls low the first body voltage BN (due to BN=REFN2+k(IN_N−IN_P)), so that the first body voltage BN is smaller than the source voltage REFN2 of the first transistor M1. The threshold voltage of the first transistor M1 is increased as the first body voltage BN is pulled low, so that a turning off operation of the first transistor M1 is accelerated. Therefore, when the second input signal IN_P is greater than the first input signal IN_N, a positive feedback path provided by the bias modulator 130 can accelerate the operation speed of the comparator 140.

Similarly, when the second input signal IN_P is smaller than the first input signal IN_N, the bias modulator 130 pulls low the second body voltage BP, so that the second body voltage BP is smaller than the source voltage REFP2 of the third transistor M3. The threshold voltage of the third transistor M3 is increased as the second body voltage BP is pulled low, so that the turning off operation of the third transistor M3 is accelerated. Conversely, the bias modulator 130 pulls high the first body voltage BN, so that the first body voltage BN is greater than the source voltage REFN2 of the first transistor M1. The threshold voltage of the first transistor M1 is decreased as the first body voltage BN is pulled high, so that the turning on operation of the first transistor M1 is accelerated. Therefore, when the second input signal IN_P is smaller than the first input signal IN_N, the positive feedback path provided by the bias modulator 130 can still accelerate the operation speed of the comparator 140.

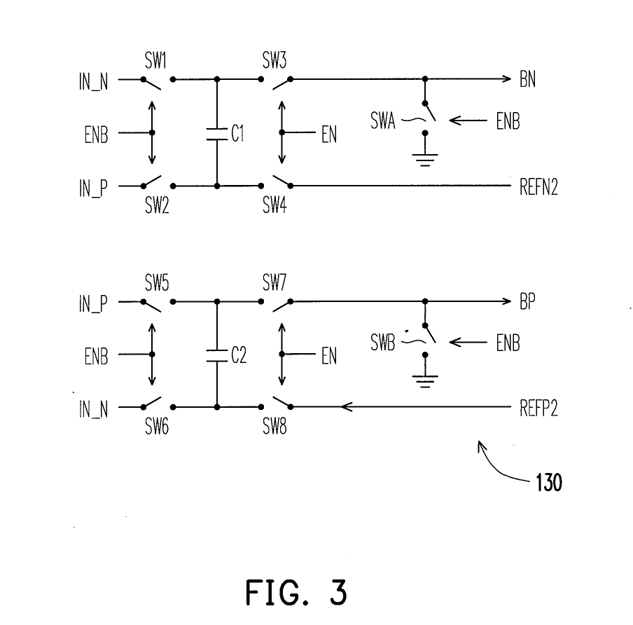

FIG. 3 is a circuit schematic diagram illustrating the bias modulator 130 of FIG. 1 according to an exemplary embodiment of the disclosure. The bias modulator 130 includes a first capacitor C1 and a second capacitor C2. A first end of the first capacitor C1 is coupled to first ends of switches SW1 and SW3, and a second end of the first capacitor C1 is coupled first ends of switches SW2 and SW4. Second ends of the switches SW1 and SW2 respectively receive the first input signal IN_N and the second input signal IN_P. A second end of the switch SW4 receives the source voltage REFN2 of the first transistor M1. A second end of the switch SW3 is coupled to the body of the first transistor M1 in the latch circuit 110. A first end of a switch SWA is coupled to the second end of the switch SW3, and a second end of the switch SWA is coupled to the ground (or coupled to the other referential voltage levels). The switches SW3 and SW4 are controlled by the enable signal EN, and the switches SW1, SW2 and SWA are controlled by the inverted signal ENB (the inverted signal of the enable signal EN).

Therefore, during a disable period of the comparator 140, for example, the enable signal EN is logic 0 and the inverted signal ENB is logic 1, the first end and the second end of the first capacitor C1 can respectively receive the first input signal IN_N and the second input signal IN_P, while the body of the first transistor M1 is coupled to the ground (or coupled to the other referential voltage levels). During an enable period of the comparator 140, for example, the enable signal EN is logic 1 and the inverted signal ENB is logic 0, the second end of the first capacitor C1 can receive the source voltage REFN2 of the first transistor M1, and the first end of the first capacitor C1 can provide the first body voltage BN to the body of the first transistor M1. If the switches SW1-SW4 are regarded as ideal switches, the first body voltage BN=REFN2+(IN_N−IN_P).

A first end of the second capacitor C2 is coupled to first ends of switches SW5 and SW7, and a second end of the second capacitor C2 is coupled to first ends of switches SW6 and SW8. Second ends of the switches SW5 and SW6 respectively receive the second input signal IN_P and the first input signal IN_N. A second end of the switch SW8 receives the source voltage REFP2 of the third transistor M3. A second end of the switch SW7 is coupled to the body of the third transistor M3 in the latch circuit 110. A first end of a switch SWB is coupled to the second end of the switch SW7, and a second end of the switch SWB is coupled to the ground (or coupled to the other referential voltage levels). The switches SW7 and SW8 are controlled by the enable signal EN, and the switches SW5, SW6 and SWB are controlled by the inverted signal ENB.

Therefore, during the disable period of the comparator 140, the first end and the second end of the second capacitor C2 can respectively receive the second input signal IN_P and the first input signal IN_N, while the body of the third transistor M3 is coupled to the ground (or coupled to the other referential voltage levels). During the enable period of the comparator 140, the second end of the second capacitor C2 can receive the source voltage REFP2 of the third transistor M3, and the first end of the second capacitor C2 can provide the second body voltage BP to the body of the third transistor M3. If the switches SW5-SW8 are regarded as ideal switches, the second body voltage BP=REFP2+(IN_P−IN_N).

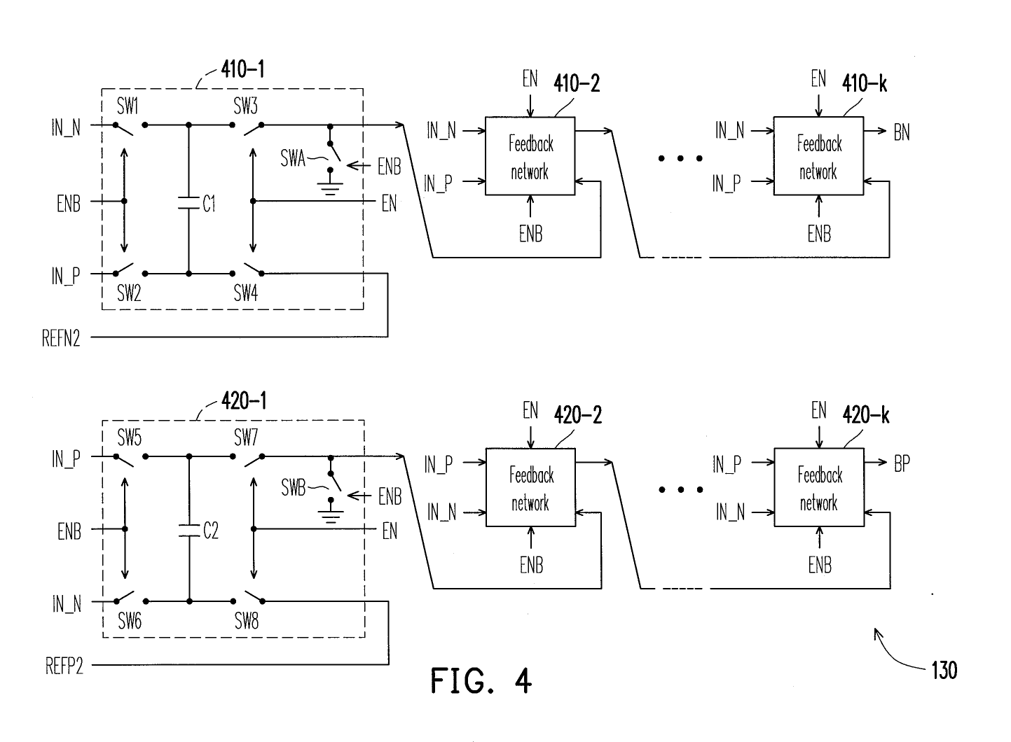

FIG. 4 is a circuit schematic diagram illustrating the bias modulator 130 of FIG. 1 according to another exemplary embodiment of the disclosure. The bias modulator 130 includes a plurality of first feedback networks 410-1, 410-2, . . . , 410-k and a plurality of second feedback networks 420-1, 420-2, . . . , 420-k. The first feedback networks 410-1˜410-k respectively have a first capacitor C1 and switches SW1, SW2, SW3 and SW4. Implementations of the first feedback networks 410-2˜410-k are the same to that of the first feedback network 410-1. The second feedback networks 420-1˜420-k respectively have a second capacitor C2 and switches SW5, SW6, SW7 and SW8. Implementations of the second feedback networks 420-2˜420-k are the same to that of the second feedback network 420-1. Related description of FIG. 3 can be referred for operation details of the first feedback network 410-1 and the second feedback network 420-1, so that detailed descriptions thereof are not repeated.

During the disable period of the comparator 140, first ends and second ends of the first capacitors C1 in the first feedback networks 410-1˜410-k respectively receive the first input signal IN_N and the second input signal IN_P, and first ends and second ends of the second capacitors C2 in the second feedback networks 420-1˜420-k respectively receive the second input signal IN_P and the first input signal IN_N. During the enable period of the comparator 140, the first capacitors C1 in the first feedback networks 410-1˜410-k are connected in series to form a first capacitor string, and the second capacitors C2 in the second feedback networks 420-1˜420-k are also connected in series to form a second capacitor string.

A second end (i.e. the second end of the first capacitor C1 in the first feedback network 410-1) of the first capacitor string receives the source voltage REFN2 of the first transistor M1, and a first end (i.e. the first end of the first capacitor C1 in the first feedback network 410-k) of the first capacitor string provides the first body voltage BN to the latch circuit 110. Similarly, a second end (i.e. the second end of the second capacitor C2 in the second feedback network 420-1) of the second capacitor string receives the source voltage REFP2 of the third transistor M3, and a first end (i.e. the first end of the second capacitor C2 in the second feedback network 420-1) of the second capacitor string provides the second body voltage BP to the latch circuit 110. If the switches SW1-SW4 in the first feedback networks 410-1˜410-k and the switches SW5-SW8 in the second feedback networks 420-1˜420-k are all regarded as ideal switches, the first body voltage BN=REFN2+k×(IN_N−IN_P), and the second body voltage BP=REFP2+k×(IN_P−IN_N).

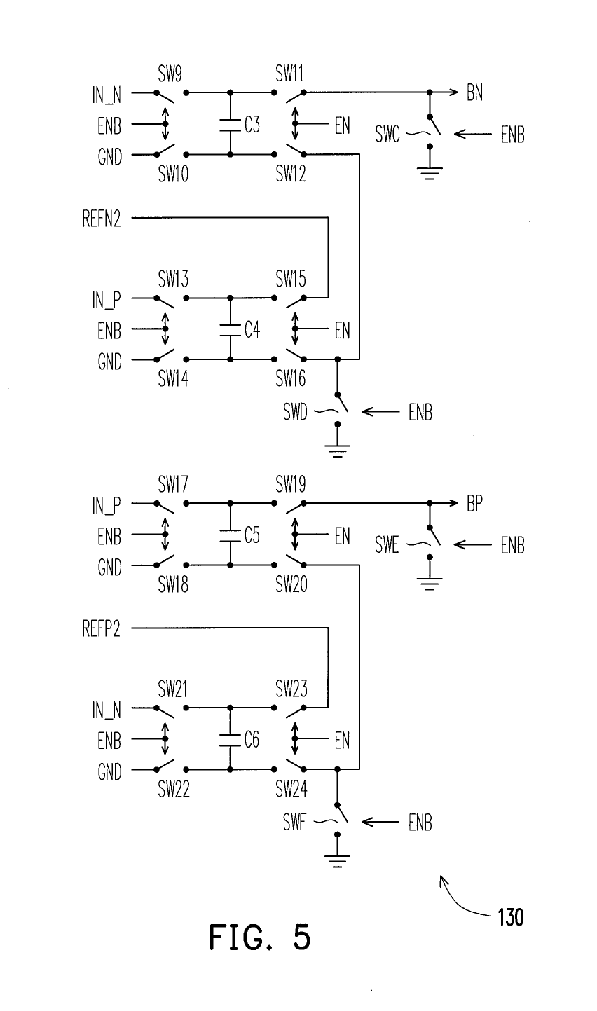

FIG. 5 is a circuit schematic diagram illustrating the bias modulator 130 of FIG. 1 according to still another exemplary embodiment of the disclosure. The bias modulator 130 includes a third capacitor C3, a fourth capacitor C4, a fifth capacitor C5 and a sixth capacitor C6. A first end of the third capacitor C3 is coupled to first ends of switches SW9 and SW11, and a second end of the third capacitor C3 is coupled to first ends of the switches SW10 and SW12. A first end of the capacitor C4 is coupled to first ends of switches SW13 and SW15, and a second end of the capacitor C4 is coupled to first ends of switches SW14 and SW16. A first end of the fifth capacitor C5 is coupled to first ends of switches SW17 and SW19, and a second end of the fifth capacitor C5 is coupled to first ends of switches SW18 and SW20. A first end of the sixth capacitor C6 is coupled to first ends of switches SW21 and SW23, and a second end of the sixth capacitor C6 is coupled to first ends of switches SW22 and SW24. Second ends of the switches SW9 and SW21 receive the first input signal IN_N. Second ends of the switches SW13 and SW17 receive the second input signal IN_P. Second ends of the switches SW10, SW14, SW18 and SW22 receive a reference voltage (for example, the ground voltage GND or any fixed voltage).

A second end of the switch SW12 is coupled to a second end of the switch SW16, and a second end of the switch SW20 is coupled to a second end of the switch SW24. A second end of the switch SW15 receives the source voltage REFN2 of the first transistor M1, and a second end of the switch SW23 receives the source voltage REFP2 of the third transistor M3. A second end of the switch SW11 is coupled to the body of the first transistor M1 in the latch circuit 110. A second end of the switch 19 is coupled to the body of the third transistor M3 in the latch circuit 110. A first end of a switch SWC is coupled to the second end of the switch SW11, a first end of a switch SWD is coupled to the second end of the switch SW15, a first end of a switch SWE is coupled to the second end of the switch SW19, and a first end of a switch SWF is coupled to the second end of the switch SW24. Second ends of the switches SWC-SWF are coupled to the ground (or coupled to the other referential voltage levels). The switches SW11, SW12, SW15, SW16, SW19, SW20, SW23 and SW24 are controlled by the enable signal EN, and the switches SW9, SW10, SW13, SW14, SW17, SW18, SW21, SW22 and SWC-SWF are controlled by the inverted signal ENB.

Therefore, during the disable period of the comparator 140, the first ends and the second ends of the third capacitor C3 and the sixth capacitor C6 respectively receive the first input signal IN_N and the reference voltage, and the first ends and the second ends of the fourth capacitor C4 and the fifth capacitor C5 respectively receive the second input signal IN_P and the reference voltage, while the bodies of the first transistor M1 and the third transistor M3 are coupled to the ground (or coupled to the other referential voltage levels).

During the enable period of the comparator 140, the second end of the third capacitor C3 is coupled to the second end of the fourth capacitor C4, the first end of the capacitor C4 receives the source voltage REFN2 of the first transistor M1, and the first end of the third capacitor C3 provides the first body voltage BN. Similarly, during the enable period of the comparator 140, the second end of the fifth capacitor C5 is coupled to the second end of the sixth capacitor C6, the first end of the sixth capacitor C6 receives the source voltage REFP2 of the third transistor M3, and the first end of the fifth capacitor C5 provides the second body voltage BP. If the switches SW9-SW24 are regarded as ideal switches, the first body voltage BN=REFN2+(IN_N−IN_P), and the second body voltage BP=REFP2+(IN_P−IN_N).

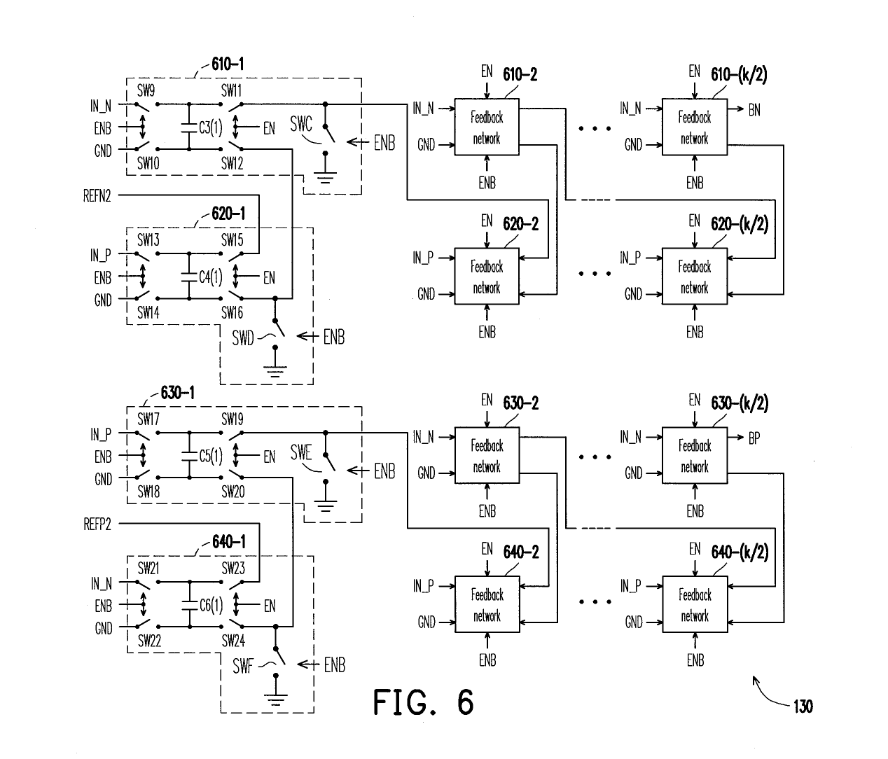

FIG. 6 is a circuit schematic diagram illustrating the bias modulator 130 of FIG. 1 according to yet another exemplary embodiment of the disclosure. The bias modulator 130 includes a plurality of third feedback networks (i.e. 610-1, 610-2, . . . , 610-(k/2) in FIG. 6), a plurality of fourth feedback networks (i.e. 620-1, 620-2, . . . , 620-(k/2) in FIG. 6), a plurality of fifth feedback networks (i.e. 630-1, 630-2, . . . , 630-(k/2) in FIG. 6), and a plurality of sixth feedback networks (i.e. 640-1, 640-2, . . . , 640-(k/2) in FIG. 6). The third feedback networks 610-1˜610-(k/2) respectively have a third capacitor C3(n) and switches SW9, SW10, SW11 and SW12, wherein 1≦n≦(k/2). Implementations of the third feedback networks 610-2˜610-(k/2) are the same to that of the third feedback network 610-1. The fourth feedback networks 620-1˜620-(k/2) respectively have a fourth capacitor C4(n) and switches SW13, SW14, SW15 and SW16. Implementations of the fourth feedback networks 620-2˜620-(k/2) are the same to that of the fourth feedback network 620-1. The fifth feedback networks 630-1˜630-(k/2) respectively have a fifth capacitor C5(n) and switches SW17, SW18, SW19 and SW20. Implementations of the fifth feedback networks 630-2˜630-(k/2) are the same to that of the fifth feedback network 630-1. The sixth feedback networks 640-1˜640-(k/2) respectively have a sixth capacitor C6(n) and switches SW21, SW22, SW23 and SW24. Implementations of the sixth feedback networks 640-2˜640-(k/2) are the same to that of the sixth feedback network 640-1. The capacitor C3(n) represents the capacitor of an n-th feedback network 610-n in the third feedback networks 610-1˜610-(k/2), the capacitor C4(n) represents the capacitor of an n-th feedback network 620-n in the fourth feedback networks 620-1˜620-(k/2), the capacitor C5(n) represents the capacitor of an n-th feedback network 630-n in the fifth feedback networks 630-1˜630-(k/2), and the capacitor C6(n) represents the capacitor of an n-th feedback network 640-n in the sixth feedback networks 640-1˜640-(k/2). Related description of FIG. 5 can be referred for operation details of the third feedback network 610-1, the fourth feedback network 620-1, the fifth feedback network 630-1 and the sixth feedback network 640-1, and therefore detail descriptions thereof are not repeated.

During the disable period of the comparator 140, first ends and second ends of the third capacitors C3(n) and the sixth capacitors C6(n) respectively receive the first input signal IN_N and the reference voltage, and first ends and second ends of the fourth capacitors C4(n) and the fifth capacitors C5(n) respectively receive the second input signal IN_P and the reference voltage. During the enable period of the comparator 140, the first end and the second end of the capacitor C3(n) are respectively coupled to the first end of the capacitor C4(n+1) and the second end of the capacitor C4(n), and the first end and the second end of the capacitor C5(n) are respectively coupled to the first end of the capacitor C6(n+1) and the second end of the capacitor C6(n). The first end of the capacitor C3(k/2) of the third feedback network 610-(k/2) provides the first body voltage BN, and the second end of the capacitor C3(k/2) is coupled to the second end of the capacitor C4(k/2) of the fourth feedback network 620-(k/2). The first end of the capacitor C4(1) receives the source voltage REFN2 of the first transistor M1, and the second end of the capacitor C4(1) is coupled to the second end of the capacitor C3(1). The first end of the capacitor C5(k/2) of the fifth feedback network 630-(k/2) provides the second body voltage BP, and the second end of the capacitor C5(k/2) is coupled to the second end of the capacitor C6(k/2) of the sixth feedback network 640-(k/2). The first end of the capacitor C6(1) receives the source voltage REFP2 of the third transistor M3, and the second end of the capacitor C6(1) is coupled to the second end of the capacitor C5(1). If the switches in the feedback networks 610-1˜610-(k/2), 620-1˜620-(k/2), 630-1˜630-(k/2) and 640-1˜640-(k/2) are all regarded as ideal switches, the first body voltage BN=REFN2+k×(IN_N−IN_P), and the second body voltage BP=REFP2+k×(IN_P−IN_N).

The bias modulator 130 of FIG. 6 receives the input differential signals of the comparator 140, and regarding the relatively small input differential signal, the bias modulator 130 can amplify a voltage difference of the input differential signal pair for k times according to a commonly used charge conservation principle of a switching capacitor module, and output the amplified voltage difference to the bodies of the transistors in the latch circuit 110, or transmit it to the bodies of the transistors in the input differential pair 120. Since the bias modulator 130 increases the positive feedback path and amplifies the input differential signals, the latch circuit 110 can accomplish the latching operation earlier. More important, during an operation process of the bias modulator 130 of the disclosure, a direct current (DC) power is not increased.

It should be noticed that although only the body voltages of the first transistor M1 and the third transistor M3 in FIG. 2A are modulated by the bias modulator 130, the disclosure is not limited thereto. For example, in another exemplary embodiment, the bias modulator 130 can further modulate a third body voltage and a fourth body voltage according to the first input signal IN_N, the second input signal IN_P, the second end (source) voltage of the second transistor M2 and the second end (source) voltage of the fourth transistor M4, and respectively provide the third and the fourth body voltages to the bodies of the second transistor M2 and the fourth transistor M4. Namely, in some exemplary embodiment, a source voltage REFN1 of the second transistor M2 is used for implementing the source voltage REFN of FIG. 1, and a source voltage REFP1 of the fourth transistor M4 is used for implementing the source voltage REFP of FIG. 1. Therefore, the third body voltage is REFN1+k(IN_N−IN_P), and the fourth body voltage is REFP1+k(IN_P−IN_N).

In summary, the exemplary embodiments of the disclosure disclose the comparator 140 having a feedback speed-up function. As described above, a pair of input signals of the comparator 140 is sent to the bias modulator 130, and the bias modulator 130 generates a pair of body voltages and outputs the body voltages to the bodies of the transistors in the latch circuit 110. Such connection provides a parallel positive feedback path for the comparator 140 or the latch circuit 110, which can accelerate the operation speed of the comparator 140. The bias modulator 130 in the exemplary embodiments of the disclosure is a switching capacitor circuit, which has a simple structure, and does not consume DC current during the operation process.

It will be apparent to those skilled in the art that various modifications and variations can be made to the structure of the present disclosure without departing from the scope or spirit of the disclosure. In view of the foregoing, it is intended that the present disclosure cover modifications and variations of this disclosure provided they fall within the scope of the following claims and their equivalents.

What is claimed is:

1. A comparison apparatus, comprising:
an input differential pair, receiving a first input signal and a second input signal;
a latch circuit, coupled to the input differential pair, wherein the latch circuit comprises a first transistor; and
a bias modulator, modulating a first body voltage according to the first input signal, the second input signal and a source voltage of the first transistor, and providing the first body voltage to a body of the first transistor.

2. The comparison apparatus as claimed in claim 1, wherein the latch circuit further comprises:
a second transistor, having a first end coupled to a first end of the first transistor, a control end coupled to a control end of the first transistor, and a body coupled to a second end of the second transistor;
a third transistor, having a control end coupled to the first end of the first transistor, and a first end coupled to the control end of the first transistor, wherein the bias modulator further modulates a second body voltage according to the first input signal, the second input signal and a voltage of a second end of the third transistor, and provides the second body voltage to a body of the third transistor; and
a fourth transistor, having a first end coupled to the first end of the third transistor, a control end coupled to the control end of the third transistor, and a body coupled to a second end of the fourth transistor.

3. The comparison apparatus as claimed in claim 2, wherein the second ends of the first transistor and the third transistor are coupled to the input differential pair, and the second ends of the second transistor and the fourth transistor are coupled to a system voltage.

4. The comparison apparatus as claimed in claim 2, wherein the first transistor and the third transistor are N-channel metal oxide semiconductor (NMOS) transistors, and the second transistor and the fourth transistor are P-channel metal oxide semiconductor (PMOS) transistors.

5. The comparison apparatus as claimed in claim 2, wherein the latch circuit further comprises:
a fifth transistor, having a first end coupled to the first end of the first transistor, a second end coupled to a system voltage, and a control end receiving an enable signal; and
a sixth transistor, having a first end coupled to the first end of the third transistor, a second end coupled to the system voltage, and a control end receiving the enable signal.

6. The comparison apparatus as claimed in claim 5, wherein the fifth transistor and the sixth transistor are PMOS transistors.

7. The comparison apparatus as claimed in claim 2, wherein the bias modulator further modulates a third body voltage according to the first input signal, the second input signal and a voltage of the second end of the second transistor and provides the third body voltage to the second transistor, and modulates a fourth body voltage according to the first input signal, the second input signal and a voltage of the second end of the fourth transistor and provides the fourth body voltage to the body of the fourth transistor.

8. The comparison apparatus as claimed in claim 7, wherein if the first input signal is IN_N, the second input signal is IN_P, the voltage of the second end of the second transistor is REFN1, and the voltage of the second end of the fourth transistor is REFP1, the third body voltage is REFN1+k(IN_N−N_P), and the fourth body voltage is REFP1+k(IN_P−IN_N), wherein k is a real number.

9. The comparison apparatus as claimed in claim 2, wherein if the first input signal is IN_N, the second input signal is IN_P, and the voltage of the second end of the third transistor is REFP2, the second body voltage is REFP2+k(IN_P−IN_N), wherein k is a real number.

10. The comparison apparatus as claimed in claim 1, wherein if the first input signal is IN_N, the second input signal is IN_P, and a source voltage of the first transistor is REFN2, the first body voltage is REFN2+k(IN_N−IN_P), wherein k is a real number.

11. The comparison apparatus as claimed in claim 1, wherein the bias modulator comprises:
a first capacitor, having a first end and a second end respectively receiving the first input signal and the second input signal during a disable period, wherein during an enable period, the first end and the second end of the first capacitor respectively provide the first body voltage and receive the source voltage of the first transistor; and
a second capacitor, having a first end and a second end respectively receiving the second input signal and the first input signal during the disable period, wherein during the enable period, the first end of the second capacitor provides a second body voltage to a body of a third transistor in the latch circuit, and the second end of the second capacitor receives a source voltage of the third transistor.

12. The comparison apparatus as claimed in claim 1, wherein the bias modulator comprises:
a plurality of first capacitors, having first ends and second ends respectively receiving the first input signal and the second input signal during a disable period, wherein during an enable period, the first capacitors are connected in series to form a first capacitor string, and a first end and a second end of the first capacitor string respectively provide the first body voltage and receive the source voltage of the first transistor; and
a plurality of second capacitors, having first ends and second ends respectively receiving the second input signal and the first input signal during the disable period, wherein during the enable period, the second capacitors are connected in series to form a second capacitor string, a first end of the second capacitor string provides a second body voltage to a body of a third transistor in the latch circuit, and a second end of the second capacitor string receives a source voltage of the third transistor.

13. The comparison apparatus as claimed in claim 1, wherein the bias modulator comprises:
a third capacitor, having a first end and a second end respectively receiving the first input signal and a reference voltage during a disable period, wherein during an enable period, the first end of the third capacitor provides the first body voltage;
a fourth capacitor, having a first end and a second end respectively receiving the second input signal and the reference voltage during the disable period, wherein during the enable period, the first end and the second end of the fourth capacitor respectively receive the source voltage of the first transistor and is coupled to the second end of the third capacitor;
a fifth capacitor, having a first end and a second end respectively receiving the second input signal and the reference voltage during the disable period, wherein during the enable period, the first end of the fifth capacitor provides a second body voltage to a body of a third transistor in the latch circuit; and
a sixth capacitor, having a first end and a second end respectively receiving the first input signal and the reference voltage during the disable period, wherein during the enable period, the first end and the second end of the sixth capacitor respectively receive a source voltage of the third transistor and is coupled to the second end of the fifth capacitor.

14. The comparison apparatus as claimed in claim 1, wherein the bias modulator comprises:
a plurality of third capacitors C3(n), having first ends and second ends respectively receiving the first input signal and a reference voltage during a disable period, wherein 1≦n≦(k/2), and k is a real number;
a plurality of fourth capacitors C4(n), having first ends and second ends respectively receiving the second input signal and the reference voltage during the disable period, wherein during an enable period, the first end and the second end of the third capacitor C3(n) are respectively coupled to the first end of the fourth capacitor C4(n+1) and the second end of the fourth capacitor C4(n), the first end and the second end of the third capacitor C3(k/2) respectively provide the first body voltage and is coupled to the second end of the fourth capacitor C4(k/2), and the first end and the second end of the fourth capacitor C4(1) respectively receive the source voltage of the first transistor and is coupled to the second end of the third capacitor C3(1);
a plurality of fifth capacitors C5(n), having first end and second ends respectively receiving the second input signal and the reference voltage during the disable period; and
a plurality of sixth capacitors C6(n), having first ends and second ends respectively receiving the first input signal and the reference voltage during the disable period, wherein during the enable period, the first end and the second end of the fifth capacitor C5(n) are respectively coupled to the first end of the sixth capacitor C6(n+1) and the second end of the sixth capacitor C6(n), the first end of the fifth capacitor C5(k/2) provides a second body voltage to a body of a third transistor in the latch circuit, the second end of the fifth capacitor C5(k/2) is coupled to the second end of the sixth capacitor C6(k/2), the first end of the sixth capacitor C6(1) receives a source voltage of the third transistor, and the second end of the sixth capacitor C6(1) is coupled to the second end of the fifth capacitor C5(1).

15. The comparison apparatus as claimed in claim 1, wherein the input differential pair comprises:
a seventh transistor, having a first end coupled to the latch circuit, and a control end receiving the first input signal; and
an eight transistor, having a first end coupled to the latch circuit, and a control end receiving the second input signal.

16. The comparison apparatus as claimed in claim 15, wherein the seventh transistor and the eighth transistor are NMOS transistors.

17. The comparison apparatus as claimed in claim 15, further comprising:
a ninth transistor, having a first end coupled to second ends of the seventh transistor and the eighth transistor, a second end coupled to ground, and a control end receiving an enable signal.

18. The comparison apparatus as claimed in claim 17, wherein the ninth transistor is an NMOS transistor.

19. A speed-up method for a comparator, the comparator comprising an input differential pair and a latch circuit, the latch circuit comprising a first transistor, and the speed-up method comprising:
modulating a first body voltage according to a first input signal and a second input signal of the input differential pair and a source voltage of the first transistor; and
providing the first body voltage to a body of the first transistor.

20. The speed-up method for the comparator as claimed in claim 19, wherein the latch circuit further comprises a second transistor, and the speed-up method further comprises modulating a second body voltage according to the first input signal, the second input signal and a source voltage of the second transistor, and providing the second body voltage to a body of the second transistor.

21. The speed-up method for the comparator as claimed in claim 20, wherein if the first input signal is IN_N, the second input signal is IN_P and the source voltage of the second transistor is REFP2, the second body voltage is REFP2+k(IN_P−IN_N), wherein k is a real number.

22. The speed-up method for the comparator as claimed in claim 19, wherein if the first input signal is IN_N, the second input signal is IN_P and the source voltage of the first transistor is REFN2, the first body voltage is REFN2+k(IN_N−IN_P), wherein k is a real number.
